(19) United States
(12) Patent Application Publication
(10) Pub. No.: US 2010/0084009 A1
(43) Pub. Date: Apr. 8, 2010

(54) Solar Cells

(75) Inventors: David E. Carlson, Williamsburg, VA (US); Murray S. Bennett, Frederick, MD (US)

Correspondence Address: CAROL WILSON;BP AMERICA INC., MAIL CODE 5 EAST, 4101 WINFIELD ROAD, WARRENVILLE, IL, 60555, US

(73) Assignee: BP Corporation North America Inc., Warrenville, IL (US)

(21) Appl. No.: 12/531,138

(22) PCT Filed: Mar. 14, 2008
(86) PCT No.: PCT/US08/57068

§ 371 Date: Sep. 14, 2009

Related U.S. Application Data
(60) Provisional application No. 60/895,217, filed on Mar. 16, 2007.

(51) Int. Cl. H01L 31/00; H01L 31/18

(52) U.S. Cl. 136/255; 136/256; 438/98; 257/E31.124; 257/E21.158

(57) ABSTRACT

A photovoltaic cell comprising a semiconductor wafer comprising a front, light receiving surface and an opposite back surface, a passivation layer on at least the back surface, a doped layer opposite in conductivity type to the wafer over the passivation layer, an induced inversion layer, a dielectric layer over the doped layer, and one or more localized emitter contacts and one or more localized base contacts on at least the back surface extending at least through the dielectric layer; and a neutral surface photovoltaic cell comprising a semiconductor wafer comprising a front, light receiving surface and an opposite back surface, neutral passivation layer on at least the back surface, a dielectric layer over the passivation layer, and one or more localized emitter contacts and one or more localized base contacts on at least the back surface extending at least through the dielectric layer.

This application claims the benefit of U.S. Provisional Patent Application 60/895,217, filed on Mar. 16, 2007.

### BACKGROUND OF THE INVENTION

This invention relates to new photovoltaic cells, also sometimes referred to herein as solar cells. More particularly, this invention relates to new photovoltaic cells that are highly efficient in converting light energy, and particularly solar energy, to electrical energy, and where such cells have electrical contacts on the back surface. This invention is also methods for making such cells.

One of the most important aspects of a photovoltaic cell is its efficiency in converting sunlight into electrical current. The art is in need of photovoltaic or solar cells that are highly efficient, and that are also easy to manufacture. The present invention provides for such solar cells and a method for their manufacture.

Although photovoltaic cells can be fabricated from a variety of semiconductor materials, silicon is generally used because it is readily available at reasonable cost and because it has the proper balance of electrical, physical and chemical properties for use in fabricating photovoltaic cells. In a typical procedure for the manufacture of photovoltaic cells using silicon as the selected semiconductor material, the silicon is doped with a dopant of either positive or negative conductivity type, formed into either ingots of monocrystalline silicon, or cast into blocks or “bricks” of what the art refers to as a multicrystalline silicon, and these ingots or blocks are cut into thin substrates, also referred to as wafers, by various slicing or sawing methods known in the art. These wafers are used to manufacture photovoltaic cells. However, these are not the only methods used to obtain suitable semiconductor wafers for the manufacture of photovoltaic cells.

By convention, and as used herein, positive conductivity type is commonly designated as “p” or “p-type” and negative conductivity type is designated as “n” or “n-type”. Therefore, “p” and “n” are opposing conductivity types.

The surface of the wafer intended to face incident light when the wafer is formed into a photovoltaic cell is referred to herein as the front face or front surface, and the surface of the wafer opposite the front face is referred to herein as the back face or back surface.

In a typical and general process for preparing a photovoltaic cell using, for example, a p-type silicon wafer, the wafer is exposed to a suitable n-dopant to form an emitter layer and a p-n junction on the front, or light-receiving surface of the wafer. Typically, the n-type layer or emitter layer is formed by first depositing the n-dopant onto the front surface of the p-type wafer using techniques commonly employed in the art such as chemical or physical deposition and, after such deposition, the n-dopant, for example, phosphorus, is driven into the front surface of the silicon wafer to further diffuse the n-dopant into the wafer surface. This “drive-in” step is commonly accomplished by exposing the wafer to high temperatures. A p-n junction is thereby formed at the boundary region between the n-type layer and the p-type silicon wafer substrate. The wafer surface, prior to the phosphorus or other doping to form the emitter layer, can be textured.

In order to utilize the electrical potential generated by exposing the p-n junction to light energy, the photovoltaic cell is typically provided with a conductive front electrical contact on the front face of the wafer and a conductive back electrical contact on the back face of the wafer. Such contacts are typically made of one or more highly electrically conducting metals and are, therefore, typically opaque. Since the front contact is on the side of the photovoltaic cell facing the sun or other source of light energy, it is generally desirable for the front contact to take up the least amount of area of the front surface of the cell as possible yet still capture the electrical charges generated by the incident light interacting with the cell. Even though the front contacts are applied to minimize the area of the front surface of the cell covered or shaded by the contact, front contacts nevertheless reduce the amount of surface area of the photovoltaic cell that could otherwise be used for generating electrical energy.

The art therefore needs photovoltaic cells that have high efficiency, can be manufactured using large scale production methods, and, preferably, in order to increase efficiency, do not have electrical contacts on the front side or surface of the wafer, thereby maximizing the available area of the front surface of the cell for converting light into electrical current. The present invention provides such a photovoltaic cell. The photovoltaic cells of this invention can be used to efficiently generate electrical energy by exposing the photovoltaic cell to the sun.

### SUMMARY OF THE INVENTION

In one aspect this invention is a photovoltaic cell comprising a semiconductor wafer comprising a front, light receiving surface and an opposite back surface, a passivation layer on at least the back surface, a doped layer opposite in conductivity type to the wafer over the passivation layer, an induced inversion layer, a dielectric layer over the doped layer, and one or more localized emitter contacts and one or more localized base contacts on at least the back surface extending at least through the dielectric layer. Preferably, the localized emitter contact or contacts and localized base contact or contacts are all on the back surface of the photovoltaic cell. The localized emitter contact and localized base contacts are suitably laser fired contacts.

In another aspect this invention is a neutral surface photovoltaic cell comprising a semiconductor wafer comprising a front, light receiving surface and an opposite back surface, a neutral passivation layer on at least the back surface, a dielectric layer over the passivation layer, and one or more localized emitter contacts and one or more localized base contacts on at least the back surface extending at least through the dielectric layer. Preferably, the localized emitter contacts and localized base contact or contacts are all on the back surface of the photovoltaic cell. The localized emitter contacts and localized base contacts are suitably laser fired contacts. By neutral surface we mean that the cell does not have a purposely induced inversion layer and, preferably, does not have an inversion layer.

This invention is also a method for making such photovoltaic cells.

### BRIEF DESCRIPTION OF THE DRAWINGS

FIG. 1 is an energy band diagram showing how an induced inversion layer in a silicon wafer “bends” the conduction and valance bands near the wafer surface so the Fermi level is closer to the conduction band.

FIG. 2 is a cross-section view of a portion of a photovoltaic cell in accordance with an embodiment of this invention having an induced inversion layer.

FIG. 3 is a cross-section view of a portion of a photovoltaic cell in accordance with an embodiment of this invention having a neutral surface.

FIG. 4 is view of the back surface of a photovoltaic cell in accordance with an embodiment of this invention showing a back contact having interdigitated fingers.

### DETAILED DESCRIPTION OF THE INVENTION

The following is a description of embodiments of the present invention but such embodiments are not to be construed as limiting the scope of this invention.

A semiconductor wafer useful in the method of this invention for preparing photovoltaic cells preferably comprises silicon and is typically in the form of a thin, flat shape. The silicon may comprise one or more additional materials, such as one or more semiconductor materials, for example germanium, if desired. For a p-type wafer, boron is widely used as the p-type dopant, although other p-type dopants, for example, aluminum, gallium or indium, will also suffice. Boron is the preferred p-type dopant. Combinations of such dopants are also suitable. Thus, the dopant for a p-type wafer can comprise, for example, one or more of boron, aluminum, gallium or indium, and preferably it comprises boron. If an n-type silicon wafer is used, the n-type dopants can be, for example, one or more of phosphorus, arsenic, antimony, or bismuth. Suitable wafers are typically obtained by slicing or sawing silicon ingots, such as ingots of monocrystalline silicon, to form monocrystalline wafers, such as the so-called Czochralski (C_{z}) silicon wafers. Suitable wafers can be obtained by slicing or sawing ingots of silicon as described in U.S. Patent Applications Publication Nos. 2007/0169684 A1 and 2007/0169685 A1, for example, silicon referred to therein as monocrystalline silicon, cast monocrystalline silicon, near-monocrystalline silicon, and geometric multi-crystalline silicon. Suitable wafers can also be made by slicing or sawing blocks of cast, multi-crystalline silicon. Silicon wafers can also be pulled straight from molten silicon using processes such as Edge-defined Film-fed Growth technology (EFG) or similar techniques. Although the wafers can be any shape, wafers are typically circular, square or pseudo-square in shape. “Pseudo-square” means a predominantly square shaped wafer usually with rounded corners. The wafers used in the photovoltaic cells of this invention are suitably thin. For example, wafers useful in this invention can be about 10 microns thick to about 300 microns thick. For example, they can be about 10 microns up to about 200 microns thick. They can be about 10 microns up to about 30 microns thick. If circular, the wafers can have a diameter of about 100 to about 180 millimeters, for example 102 to 178 millimeters. If square or pseudo-square, they can have a width of about 100 millimeters to about 150 millimeters with rounded corners having a diameter of about 127 to about 178 millimeters. The wafers useful in the process of this invention, and consequently the photovoltaic cells made by the process of this invention can, for example, have a surface area of about 100 to about 250 square centimeters. The doped wafers that are useful in the process of this invention can have a resistivity of about 0.1 to about 20 ohm.cm, typically of about 0.5 to about 5.0 ohm.cm.

The wafers used in the photovoltaic cells of this invention preferably have a diffusion length (L) that is greater than the wafer thickness (t). For example, the ratio of L to t is suitably greater than 1. It can, for example be greater than about 1.1, or greater than about 2. The ratio can be up to about 3 or more. The diffusion length is the average distance that minority carriers (such as electrons in p-type material) can diffuse before recombining with the majority carriers (holes in p-type material). The L is related to the minority carrier lifetime τ through the relationship L=(DT)^{1/2} where D is the diffusion constant. The diffusion length can be measured by a number of techniques such as the Photon-Beam-Induced Current technique or the Surface Photovoltage technique. See for example, “Fundamentals of Solar Cells”, by A. Fahrenbruch and R. Bube, Academic Press, 1983, pp. 90-102, which is incorporated by reference herein, for a description of how the diffusion length can be measured.

Although the term wafer, as used herein, includes the wafers obtained by the methods described, particularly by sawing or cutting ingots or blocks of single crystal or multi-crystalline silicon, it is to be understood that the term wafer can also include any other suitable semiconductor substrate or layer useful for preparing photovoltaic cells by the process of this invention. Any damage created by sawing or cutting wafers from ingots can be removed by etching the wafers in sodium hydroxide (NaOH) at an elevated temperature; for example, a solution of 40 wt % NaOH in water at about 80° C. The wafers can be cleaned by, for example, using a standard RCA clean followed by a dip in dilute hydrofluoric acid (HF) for example, about 5% wt % HF in water.

The front surface of the wafer is preferably textured. Texturing generally increases the efficiency of the resulting photovoltaic cell by increasing light absorption. For example, the wafer can be suitably textured using chemical etching, plasma etching, laser or mechanical scribing. If a monocrystalline wafer is used, the wafer can be etched to form an anisotropically textured surface by treating the wafer in an aqueous solution of a base, such as sodium hydroxide, at an elevated temperature, for example about 70° C. to about 90° C. for about 10 to about 120 minutes. The aqueous solution may contain an alcohol, such as isopropanol. A multicrystalline wafer can be textured by mechanical dicing using beveled dicing blades or profiled texturing wheels. In a preferred process a multicrystalline wafer is textured using a solution of hydrofluoric acid, nitric acid (HNO₃) and water. Such a texturing process is described by Hauser, Melnyk, Fath, Narayanan, Roberts and Bruton in their paper “A Simplified Process for Isotropic Texturing of MC—Si”, Hauser, et al., from the conference “3^{rd} World Conference on Photovoltaic Energy Conversion”, May 11-18, Osaka, Japan, which is incorporated by reference herein in its entirety. The textured wafer is typically subsequently cleaned, for example, by immersion in hydrofluoric and then hydrochloric acid with intermediate and final rinsing in de-ionized water, followed by drying. The back surface of the wafer may or may not be textured depending on the thickness of the wafer and the light-trapping geometry employed.

Prior to texturing a wafer, the wafer can be subjected to phosphorus and/or aluminum gettering. For example, gettering can be accomplished by forming a heavily doped n-type layer (n⁺ layer) by, for example, phosphorus diffusion on one or both sides of the wafer. This can be accomplished, for example, by exposing the wafer to a gas such as POCl₃, for 30 minutes at 900° C. to 1000° C. Such gettering will increase the diffusion length of the wafer. After formation of the heavily doped n-type layer or layers, they can be removed by, for example, etching using acids such as HF and HNO₃ or a mixture thereof, or strong bases such as NaOH. One embodiment of this invention would involve forming a heavily doped n-type layer on the front of the wafer to getter impurities and then subsequently removing it during the texture etching of the front surface as described above.

### I. The Induced-Inversion-Layer Back-Contact Photovoltaic Cell

In one aspect, this invention is a back contact photovoltaic cell comprising an induced inversion layer. This cell comprises passivated, more suitably, well-passivated silicon wafer surfaces and also preferably comprises an induced emitter, also referred to herein as an induced inversion layer, in conjunction with localized contacts that are, preferably, fired through a dielectric layer. By localized we mean that the contacts do not occupy the total back surface of the photovoltaic cell and, preferably, the total area of all the localized contacts is only a small percentage of the total area of the back surface of the photovoltaic cell, such as no more than about 5 percent, or no more than about 3 or 2 percent of the total area of the back surface of the photovoltaic cell.

The silicon wafers, which can be either p-type or n-type, are preferably cleaned and the front surface may be textured. Then, at least the back surface of the wafer, or the front and back surfaces of the wafer, or all surfaces of the wafer, are coated with one or more, preferably thin, passivating layers, for example, a layer of amorphous silicon (a-Si:H) that is up to about 30 nanometers (nm) thick, for example, about 4 to about 30 nm thick. The passivation layer can be about 10 nm thick. This passivation layer may also be an undoped, or so-called intrinsic layer of an a-Si:H alloy such as a-SiNₓC_{y}O_{z}:H comprising varying amounts of carbon, nitrogen and oxygen. There may be one or more of such layers to form the passivation layer where the total thickness of the single layer or all the layers is about 4 to about 30 nm. The values of x, y and z can be such that they each vary from about 0 to less than about 0.66. However, in the case of nitrogen and oxygen, the composition may be close to stoichiometric, so that instead of it being a-Si:H it is more nearly the composition of silicon nitride in the case of adding N, or silicon dioxide in the case of adding O. Layers of a-Si:H with or without added C, N or O that are deposited by plasma enhanced chemical vapor deposition (PECVD), also typically contain 5-20 at. % of hydrogen. Ammonia can be used as a suitable source of nitrogen. Low molecular weight hydrocarbons, most suitably methane, are suitable sources of carbon. Oxygen gas is a suitable source of oxygen, but other oxygen containing gases such as CO₂ or N₂O may also be used as a source of oxygen. Such a-Si:H layer can be applied by any suitable method such as, for example, by PECVD in an atmosphere of silane. Most suitably, it is applied by PECVD in an atmosphere containing about 10% silane in hydrogen, and most suitably it is applied at low temperatures such as, for example, about 100° C. to about 250° C.

Without intending to be bound by a theory of operation, this passivation layer is added to passivate defects near the surface of the silicon wafer. After such passivation layer or layers are applied, the wafer silicon surface recombination velocity should be ≦100 cm/s for the coated silicon wafer surfaces, for example, ≦40 cm/s, and preferably ≦10 cm/s. The surface recombination velocity (S) at the surface of a silicon wafer is determined by measuring the effective lifetime of a wafer (τ_{eff}) using techniques such as photoconductive decay (the effective lifetime can be measured using the microwave photoconductive decay technique with the WT-2000 Wafer Tester made by Semilab) and by also determining the bulk lifetime (τ_{b}) of the silicon used to make the wafer, and then using the expression 1/τ_{eff}=1/τ_{b}+2S/W where W is the sample thickness to determine S. The bulk lifetime can be determined by measuring the effective lifetime of a similar silicon wafer having extremely well passivated surfaces so that τ_{eff}=τ_{b}. The silicon surfaces can be extremely well passivated by, for example, by immersing the wafer in a solution of 10% hydrogen fluoride (HF) in water for a few minutes at room temperature before measuring the lifetime. For silicon surfaces with aluminum back-surface field contacts, S is usually >1,000 cm/s.

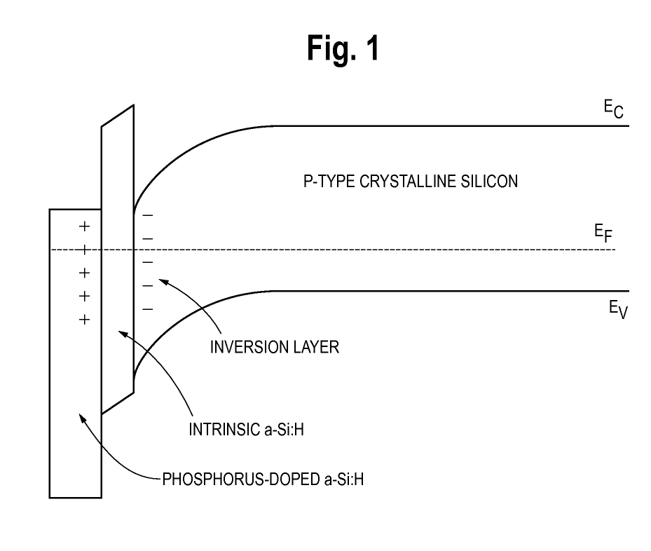

After adding the one or more passivating layers, one or more, preferably, thin layers of a doped layer having a conductivity type or doping opposite to that of the wafer is applied to at least the back surface of the wafer. The doped layer or layers can be applied to both the back and front surfaces of the wafer, and can be applied to all surfaces of the wafer. Such doped layer, preferably, heavily doped a-Si:H, is for example, about 10 to about 30 nm thick, of a conductivity type opposite to the wafer. If the wafer is p-type, the doped layer such as an a-Si:H layer can be doped with, for example, one or more of phosphorus, arsenic, antimony or bismuth. If the wafer is n-type, the layer can be doped with, for example, one or more of boron, aluminum, gallium or indium. The doped layer may also be an alloy such as phosphorus-doped a-SiC_{y}:H for generating an inversion layer in a p-type wafer, and boron-doped a-SiC_{y}:H for generating an inversion layer in an n-type wafer. The concentration of dopant, such as, for example, phosphorus, can be about 0.1 to about 1.0 atomic % (at. %). The doped layer can also be a doped alloy a-SiNₓC_{y}O_{z}:H, where x can be in the range of about 0 to about 0.2 and y and z can be in the range of about 0 to about 0.05. The doped layer can be applied in any suitable manner such as, for example, by PECVD. Without intending to be bound by a theory of operation, the passivation layer capped by a doped layer induces an inversion layer or induced emitter in the silicon wafer. The passivation and doped layers can be deposited on all surfaces of the wafer, that is the front, back, and edges of the wafer. Preferably, the inversion layer is adjacent to all surfaces of the wafer. Again, without intending to be bound by a theory of operation, such inversion layer generated over the entire surface of the wafer would minimize any polarization or charging effects that might occur in operating photovoltaic modules having photovoltaic cells made in accordance with this embodiment of the invention. An inversion layer is created in silicon when sufficient charge is induced near the surface so that the minority carriers in the bulk become the majority carriers near the surface. In the case of p-type silicon, where holes are the majority carriers and the Fermi level is close to the valence band, one can induce an inversion layer by locating a layer containing fixed positive charge near the silicon surface or by locating an n⁺, for example, phosphorus-doped, silicon layer near the surface of the silicon wafer. FIG. 1 shows an energy band diagram for the case where an intrinsic layer of undoped a-Si:H is deposited on p-type crystalline silicon and then a phosphorus doped (n⁺) layer of a-Si:H is deposited on the intrinsic a-Si:H layer. In this case, the phosphorus-doped a-Si:H layer will induce an inversion layer containing negative charge (excess electrons) near the surface of the p-type crystalline silicon. Thus, as shown in FIG. 1, the conduction and valence bands (E_{C} and E_{B}, respectively) will bend such that the Fermi level (E_{F}), in equilibrium, will be closer to the conduction band near the surface. In another example, the fixed positive charge in silicon nitride deposited by PECVD, which typically has a charge density of about 2×10¹² cm⁻², will induce a negatively charged or inversion layer near the surface of a p-type wafer, which causes the conduction band near the surface to move closer to the Fermi level. However, it is desirable to induce a strong inversion layer, so the preferred embodiment would employ a heavily doped layer, such as a heavily doped layer of a-Si:H or an a-Si:H alloy containing, for example, carbon. For example, in the case of a p-type wafer, the doped layer can be an a-Si:H layer or a a-SiC_{y}:H layer (y is >0) that can be 30 nm thick and containing about 0.5 to about 2.0 at. % n-type dopant, such as 1.0 at. % of an n-type dopant such as phosphorus, and in the case of an n-type wafer the doped layer can be an a-Si:H layer or a a-SiC_{y}:H layer (y is >0) that can be 30 nm thick and containing 0.5 to about 2.0 at. % p-type dopant, such as about 1.0 at. % a of p-type dopant such as boron. By a “strong” inversion layer, we mean, preferably, an inversion layer where the amount of induced charge causes the wafer surface to become degenerate or very conductive, such as an electrical conductivity that is close to metallic.

In another embodiment, the passivation layer and doped layer can be replaced by one or more lightly doped layers. For example, a lightly doped layer of a-Si:H. In the case of a p-type wafer, the layer can be a-Si:H, and the layer can be about 10 to about 50 nm thick, and the layer can contain about 0.01 to about 0.3 at. % n-type dopant, such as one or more of phosphorus, arsenic, antimony, or bismuth. For example, a layer of a-Si:H that is 30 nm thick and containing about 0.1 at. % of phosphorus. In the case of an n-type wafer, the layer can be a-Si:H, and the layer can be about 10 to about 50 nm thick, and the layer can contain about 0.01 to about 0.3 at. % p-type dopant, such as one or more of boron, aluminum, gallium, or indium. For example, a layer of a-Si:H that is 30 nm thick and containing about 0.1 at. % of boron. In this case, the lightly doped a-Si:H layer forms a heterojunction with silicon, and as before, the doped layer induces an inversion layer in the silicon wafer.

One or more layers of dielectric material, such as a layer silicon nitride, for example is then deposited on the front of the wafer, more preferably on the front and back of the wafer, and most preferably, all surfaces of the wafer. If deposited by PECVD, the silicon nitride can be a-SiNₓ:H where x is suitably about 0.4 to about 0.57. The dielectric layer can be up to about 90 nm thick, for example, about 70 to about 90 nm thick. The dielectric may also be other materials such as a-SiNₓC_{y}O_{z}:H deposited by, for example, PECVD, and comprising varying amounts of carbon, nitrogen and oxygen. The values of x, y and z can be such that they each vary from about 0 to less than about 0.66. The relative amounts of carbon, nitrogen and oxygen in the a-SiNₓC_{y}O_{z}:H may be selected to minimize light absorption in the dielectric layer and to optimize light coupling into the silicon wafer. In the preferred case, the dielectric layer on the front and its thickness are selected to minimize light absorption in the dielectric and to optimize the light coupling into the silicon wafer, and the type of dielectric layer on the back and its thickness are selected to enhance reflection of weakly absorbed radiation back into the silicon wafer. In both cases, the composition of the dielectric layer on the front surface may be graded to optimize the light trapping. Grading means that the composition of the dielectric, for example the concentration of carbon and/or nitrogen in the dielectric on the front surface of the wafer, changes by decreasing from the part of the dielectric layer closest to the front to the part of the dielectric layer closest to the doped layer. Thus, the dielectric constant of the graded layer on the front surface would decrease from the outer surface to the doped layer of the sample so as to reduce reflection at the front surface. At the back surface alternating layers of dielectric materials with different dielectric constants can be deposited to optimize reflection of weakly absorbed radiation back into the silicon wafer. For example, a layer of SiNₓ:H, where x is about 0.4 to about 0.57, might be deposited on the doped layer and then overcoated with a layer of a-SiO_{z}:H, where z is about 0.5 to about 0.66, with the thicknesses of the layers selected to minimize reflection. In most cases, the dielectrics and thicknesses of the dielectric layers on the front of the cells would be selected to minimize light absorption in the layers and to minimize reflection from the cells when encapsulated in a photovoltaic module.

The photovoltaic cells in accordance with embodiments of this invention have localized electrical contacts, preferably only on the back surface of the wafer. These localized contacts extend through at least the dielectric layer, and preferably through the doped layer and the passivation layer (or the lightly doped, thicker layer if that layer is used to replace the combination of the passivation and doped layers) and into the silicon wafer. In one embodiment of the invention, materials, such as a metal or non-metal, that can form localized n⁺ contacts, or pastes or inks that contain n-type dopants, such as one or more of As, Bi, P or Sb; and materials, such as a metal or non-metal, that can form localized p⁺ contacts, or pastes or inks that contain p-type dopants, such as one or more of Al, B, Ga or In, are applied in a pre-selected pattern on the wafer to form the localized contacts. One of the advantages of this invention is that the these localized base and emitter contacts can, as will be described in more detail below, be readily formed on the wafer by treating the back surface of the wafer after the passivation layer, doped layer (or the lightly doped, thicker layer if that layer is used to replace the combination of the passivation and doped layers), and dielectric layer have been applied. The pattern is preferably formed by applying the materials locally, that is, in a manner so that the material is applied only where it needs to be rather than in, for example, a manner that covers the entire surface of the wafer. The pattern is preferably selected so that, ultimately, the localized contacts can be easily electrically connected, as described in more detail below, to form two separate photovoltaic cell electrical contacts, one that is the positive electrical contact for the photovoltaic cell and the other the negative electrical contact. The material can be applied onto the dielectric layer on the back surface of the wafer in a series of separated dots or short lines, or in some other pattern such as a continuous line. A series of separated dots is preferred. One such preferred pre-selected pattern is an interdigitated finger pattern on, preferably, only the back dielectric layer, where the first part of the interdigitated finger pattern is the material comprising the p-type material for the p⁺ localized contacts and the other, second part of the interdigitated finger pattern is material comprising the n-type material for the n⁺ localized contacts. By interdigitated finger pattern we mean a pattern where a first set of, preferably parallel, rows or “fingers” of the material are applied between a second set of such “fingers”. The material can be applied in a series of isolated “dots” or short lines, or in some other pattern, to form each finger. As series of separated dots is preferred. Such interdigitated finger pattern can be visualized by placing the fingers of a hand between, but separated from, the fingers of another hand, in an alternating manner. One hand and its fingers would form one contact and the other hand, the other contact. The interdigitated finger patterns of dots or lines will be overcoated with an interdigitated pattern of conductive fingers to collect the photogenerated current.

A laser, other source of radiation, or a source of heat, or other suitable method, can be used to fire the p-type and n-type materials through the dielectric, through the doped and through the passivation layers forming both p⁺ and n⁺ localized contacts to io the silicon wafer. Laser firing can be accomplished using, for example, a Nd-YAG laser. For example, the laser can be a Q-switched, Nd-YAG laser having a pulse duration of, for example, about 10 to about 200 nanoseconds. If the p-type and n-type materials are deposited as separated dots, or separated short lines and then fired as described above, the localized emitter and base contacts so formed will also be separated from each other on the wafer.

In another embodiment, the localized p⁺ and n⁺ contacts are formed by thermal treatment, such as a rapid thermal processing, but in this case the passivation, doping and dielectric layers should be able to withstand the thermal processing, for example, where the passivation and doping layer might comprise a-SiC_{y}:H alloy where y can be in the range from about 0 to about 0.2. For example, a composition might be 75 at. % Si, 15 at. % C and 10 at. % H. In this case, the layers on the surface of the wafer could be first opened, for example by etching, through the dielectric, doped and passivation layers (or the lightly doped, thicker layer if that layer is used to replace the combination of the passivation and doped layers) in a pre-selected pattern as described above so that the p-type and n-type material being used to form the contacts can be placed in contact with the silicon wafer in those opened regions. The opened regions, such as in the shape of separated round holes, or short lines or other suitable shape, could also be formed using laser ablation. Alternatively, the dopant-containing material can be applied locally on top of the dielectric layer in a pre-selected pattern as described above if it can be thermally fired through the dielectric, doped and passivation layers (or the lightly doped, thicker layer if that layer is used to replace the combination of the passivation and doped layers) and on or into the silicon layer beneath the dielectric, doped and passivation layers. A rapid thermal processing can be accomplished by heating the silicon at least in the region where the desired p⁺ or n⁺ localized contact is to be formed for a short time period, such as about 5 seconds to about 2 minutes at a temperature of, for example, about 700° C. to about 1000° C.

The dopant-containing materials used to form the localized contacts can be metals, such Al, Ga or In, for p⁺ contacts, and Sb, As or Bi, for n⁺ contacts, deposited by or more methods such as vapor deposition, or they can be alloys such as, for example Sn—Sb, Sn—Bi for the n⁺ contacts, or Sn—In, Al—Si for the p⁺ contacts. The dopant-containing materials used to form the localized contacts can be inks or pastes comprising compounds, such as one or more of SbN or AsP, that can form n⁺ contacts or one or more of B₂Si or AlB₂ , that can form p⁺ contacts, or organometallic compounds containing, for example, one or more of B, Al, Ga or In, that can form p⁺ contacts or one or more of P, As, Sb, Bi that can form n⁺ contacts. The number of such localized contacts and the spacing and shape of the localized contacts will, preferably, be selected to achieve optimal photovoltaic cell performance.

Minority carriers that may collect in the inversion layer during the operation of the photovoltaic cell may leak to the base contacts, that is, the p⁺ localized contacts in a p-type wafer and the n⁺ localized contacts in an n-type wafer. Such leakage would decrease the efficiency of the photovoltaic cell in converting light energy into electrical energy. These base contacts are ohmic contacts to the wafer that allow the collection of majority carriers. This leakage or shunting can be prevented or minimized by, for example, electrically isolating the base contact from the inversion layer. This electrical isolation can be accomplished by, for example, adding an insulation layer between at least part of and preferably all of the base contact and the inversion layer. The insulation layer is preferably a dielectric material, such as one or more of SiO₂, intrinsic a-Si:H, or SiNₓC_{y}O_{z}:H, where the values of x, y and z can be such that they each vary from about 0 to less than about 0.66. If the base contacts are “point” contacts, such as, for example, a contact made by laser or thermally firing a dot or short line of the material used to form the contact through the dielectric, doped and passivation layers, the electrical isolation can be accomplished by forming a ring or collar of electrically insulating material, such as one or more dielectric materials mentioned above, around the base contacts. Such an isolation ring or collar can be made by depositing a layer or region of the selected dielectric material in the form of, for example, an ink or paste over the dielectric layer in the areas where the base contacts will be formed. Then, using, for example, a laser, the dielectric material can be fired or fused through at least the dielectric layer and the doped layer. The dielectric material could be fired or fused through the dielectric layer, for example, silicon nitride, the doped layer, and the passivation layer all the way to the wafer and even into the silicon wafer to some extent. The material used to form the base contacts can then be deposited over the same area and then, as describe above, fired through the dielectric material using a laser and thereby forming the base contact having a ring or collar of dielectric material surrounding the material used to form the base contact so there is no significant inversion layer induced in the silicon wafer in the vicinity of the isolation ring or collar. Such isolation ring can also be formed by a rapid thermal processing step where the dielectric material use to form the isolation ring is, for example, a glass frit paste or ink that fuses through at least the dielectric layer and the doped layer so that no significant inversion layer is formed in the silicon in the vicinity of the isolation ring. At least a portion, and preferably all of the base contacts have an insulation layer electrically isolating the base contact from the inversion layer.

A pre-selected pattern, such as an interdigitated finger pattern described above, comprising an electrically conductive material, or a material that will become electrically conductive after subsequent thermal or other treatment, is deposited over the localized emitter contacts and over the localized base contacts to separately electrically connect each set of contacts so that electric current can be collected from the operating photovoltaic cell.

For example, the pre-selected, electrically conductive pattern can comprise silver, aluminum or other suitable metal, and the silver, aluminum or other suitable metal can be applied to the wafer by one or more deposition methods. For example the pattern can be applied by applying an aluminum containing paste or inkjet printing a silver containing ink. Firing or otherwise thermally treating such pastes would convert it into a stable, electrically conducting contact.

In one embodiment, using a p-type wafer, for example, the base and emitter localized contacts, the isolating rings and the electrically conductive pattern, for example, an interdigitated finger pattern, that electrically connects the localized contacts can be formed using a multi-headed, inkjet printer. In such embodiment, one head prints, for example, dots or other suitable shapes of an ink containing an n-type contact material such as antimony, another head prints an interdispersed array of dots containing a p-type contact material such as aluminum, another head prints a ring of material to be used to form the isolation ring around the p-type dots (for a p-type wafer), and another head prints the pattern of electrically conductive material, such as interdigitated fingers of silver containing paste or ink, with a first pattern, such as a finger pattern, over the p-type dots (or other suitable shapes) and the associated isolation rings, and a second pattern over the n-type dots (or other suitable shapes), such as a finger pattern, electrically separated from the first pattern. Then a laser is used to fire the n⁺ contacts and to simultaneously fire both the p⁺ contacts and the material for forming the isolation rings to form the localized emitter contacts and localized base contacts having the isolation ring, respectively. In another embodiment, again using a p-type wafer as an example, one print head of a multi-headed inkjet printer would first print the isolation ring material onto the dielectric layer, another head prints a first pattern, for example, finger pattern, of p-type material such as an Al-containing ink over the isolation ring material, another head prints a second pattern, for example, finger pattern, of an n-type material, such as an Sb-containing ink, separated from the first pattern, and then another head prints a electrically conductive material such as a Ag-containing ink in an interdigitated finger pattern over both the patterns of p-type and n-type materials. Then a laser is used to form n⁺ localized contacts in selected regions of the patterns containing the n-type materials and another laser beam is used to both form p⁺ localized contacts in the central regions of the isolation ring material as well as fusing the isolation ring material at least into the dielectric and doped layers as mentioned above. Alternatively, as also mentioned above, the localized contacts might be formed by rapid thermal processing, but, preferably, in this case conditions for the rapid thermal processing should be selected so that the material used to form the electrically conducting patterns that electrically connect the localized contacts does not fire through the dielectric layer.

In the case of laser-fired contacts, a thermal annealing step may be used to optimize the performance of the photovoltaic cell. Such annealing can be accomplished, for example, by heating the cell to a temperature of about 300° C. to about 450° C., for about 5 to about 60 minutes, for example, at about 350° C. for 30 minutes. It can be annealed by rapid thermal processing, for example, at about 700° C. to about 1000° C., for about 5 seconds to about 2 minutes, for example, at about 700° C. for about 1 minute. In both cases, the passivation and dielectric layers selected must be able to tolerate such annealing step.

II. The Neutral Surface Back-Contact Photovoltaic Cell

In another aspect, this invention is a photovoltaic cell referred to herein as a neutral surface back-contact photovoltaic cell. That is, there is no purposely induced charge or band bending near the surface of the wafer that could induce shunting or current leakage near the localized contacts.

To form the neutral surface back-contact photovoltaic cell, a passivation layer that contains no or no significant fixed charges is applied to the wafer, such as a layer of a-Si:H. It can be one or more such layers. The passivation layer or layers can be applied on the back surface of the wafer, on the back and the front surfaces of the wafer, or to all surfaces of the wafer. The wafer can be p-type or n-type. Such neutral passivation layer or layers can be as described above for the passivation layers for the induced inversion layer cell; however, for this aspect of the invention, the passivation layer or combination of passivation layers, such as a layer of a-Si:H, may be thicker than the passivation layer or layers for the induced inversion layer cell. For example, such neutral passivation layer or combination of such layers can be up to about 100 nm thick; for example about 4 to 100 nm thick. The neutral passivation layer on the back surface of the wafer should be thick enough to provide dielectric isolation of the pattern of electrically conductive material on the back of the wafer from the silicon wafer outside those regions where localized contacts are formed. Also, the neutral passivation layer should be thick enough to greatly reduce or eliminate the formation of an inversion layer or an accumulation layer at the surface of the wafer. Without intending to be bound by a theory of operation, it is believed an a-Si:H passivation layer, if made thick enough, can provide enough charge of the opposite polarity to compensate the charge in any dielectric layer that is deposited over the a-Si:H layer. The deposition of such dielectric layer is described in more detail below. For example, SiNₓ:H deposited by PECVD typically has a positive charge density of about 2×10¹² cm⁻² while SiO₂ typically has a positive charge density of about 10¹¹ cm⁻². Thus, a thin a-Si:H passivation layer, for example, a layer about 5 to about 50 nm thick, can be used in conjunction with an SiO₂ dielectric layer to prevent a significant inversion layer from forming in the p-type silicon wafer, while a much thicker passivation a-Si:H layer, for example about 30 to about 100 nm thick, would need to be used with a SiNₓ:H dielectric layer to prevent a significant inversion layer from forming in the p-type silicon wafer. The thickness of the a-Si:H layer will depend on the conductivity of the a-Si:H, which is determined by the deposition conditions such as substrate temperature, residual impurities, and other variables. In another embodiment of the neutral surface back-contact photovoltaic cell, a layer of intrinsic a-Si:H could be used as both a passivation layer and as a dielectric layer, and in this case the thickness of the a-Si:H might be about 40 to about 100 nm thick.

A thin, doped layer can also be used over the passivation layer or layers in the neutral surface back-contact photovoltaic cell, such as, preferably, a layer of doped a-Si:H, to assure a neutral surface condition in the silicon wafer so that there is no significant inversion or accumulation layer. The dopant can be one or more of a p-type dopant such as boron, aluminum, gallium, indium or one or more of an n-type dopant such as phosphorus, arsenic, antimony and indium. The amount of dopant can be experimentally determined by determining the zero band bending condition using, for example, surface photovoltage measurements. The magnitude of photovoltage will depend on the amount of band bending and the polarity of the photovoltage will depend on the direction of the band bending. The photovoltage will be close to zero when the band bending is close to zero. An inversion layer can occur, for example, when a layer containing fixed positive charge, such as a layer of SiNₓ:H, is located near the surface of a p-type wafer so that minority carriers, that is, electrons in a p-type wafer or holes for an n-type wafer, dominate near the surface and the conduction and valence bands bend so that the Fermi level is brought close to the conduction band. One or more thin layers, for example, about 4 to about 20 nm thick, lightly doped with one or more of a p-type dopant, for example, boron, aluminum, gallium or indium, can be used to compensate or negate the fixed positive charge that might exist in the dielectric layer. The layer can be a-Si:H. For example, for a dielectric layer of SiNₓ:H with a fixed positive charge density of about 2×10¹² cm⁻², a thin layer of a-Si:H doped with boron can be used to assure that no inversion layer or accumulation layer occurs in the silicon wafer. The thin doped layer might contain, for example, about 0.001 at. % p-type dopant, such as boron, to about 0.1 at. % p-type dopant, depending on the thickness of the doped layer and the amount of fixed positive charge in the dielectric layer. Such a doped layer or layers, if used, is preferably optimized in terms of thickness, dopant type and dopant concentration to assure that the conduction and valence band bending near the surface of the silicon wafer is at or essentially zero. Conversely, if the dielectric layer should contain fixed negative charge, then one or more thin layers, for example, about 4 to about 20 nm thick lightly n-doped an n-type dopant, such as one or more of phosphorus, arsenic, antimony or bismuth, at a doping level of about 0.001 at. % n-type dopant to about 0.1 at. % n-type dopant, is preferably applied over the passivation layer or layers. Preferably, the thickness of the n-doped layer would depend on the doping level and on the fixed negative charge in the dielectric layer, and is, preferably selected to assure that no or substantially no charge is induced at the silicon wafer surface.

One or more layers of dielectric material are applied to the wafer over the passivation layer and, if present, over the thin doped layer in the neutral surface back-contact photovoltaic cell. The one or more dielectric layers can be applied to the back surface of the wafer, to the back and front surfaces of the wafer, or to all surfaces of the wafer. Such dielectric layer or layers can be as described above for the dielectric layer for the induced inversion layer cell, but may be optimized, for example, by depositing the dielectric under conditions so that there is no or essentially no fixed charge in the dielectric, so that no significant conduction or valence band bending or induced charge occurs in the silicon. A neutral surface with no significant band bending can usually be achieved with the deposition of intrinsic a-Si:H on a well-cleaned silicon wafer. As mentioned above, SiNₓ:H typically has a positive charge density of about 2×10¹² cm^{-2,} while SiO₂ typically has a positive charge density of about 10¹¹ cm⁻². As also mentioned above, any charge in the dielectric layer could be negated or compensated by using an appropriate doped layer.

The localized contacts for this neutral surface, back-contact photovoltaic cell can be applied in a manner as described above for the induced inversion layer cell. As described above for the induced inversion layer cell, such localized contacts are preferably formed on the wafer for the neutral surface back-contact photovoltaic cell after the deposition of the layers described above on the back face of the wafer. Thus, the base and emitter contacts for the neutral surface back-contact photovoltaic cell extend through the dielectric layer and preferably through the passivation layer (and thin doped layer if used.)

Isolation rings, as described above for the induced inversion layer cell, are optional for this neutral surface, back-contact photovoltaic cell. However, if used, they can be formed as described above for the induced inversion layer cell.

The electrical contacts formed from electrically conductive material that electrically connects the emitter localized contacts on neutral surface back-contact photovoltaic cell, and electrically connects the localized base contacts on neutral surface back-contact photovoltaic cell, can be applied to the back surface of the photovoltaic cell as described above for the induced inversion layer cell. The pattern can be, for example, in the form of interdigitated fingers, or some other suitable pattern. If laser firing is used to form the localized contacts, a thermal annealing step as described above for the induced inversion layer cell might be required to optimize the performance of the photovoltaic cell.

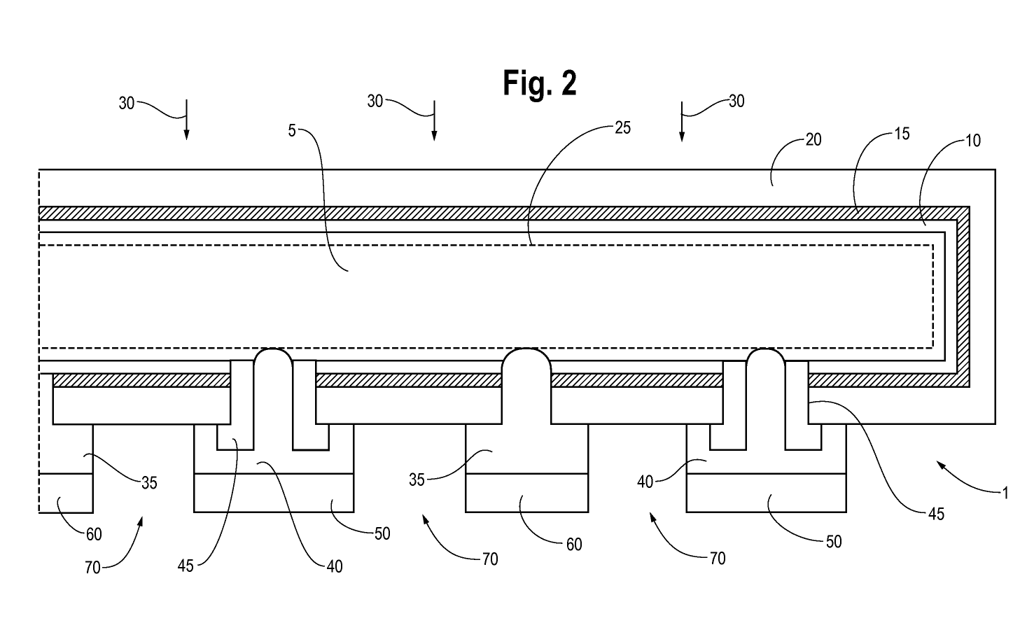

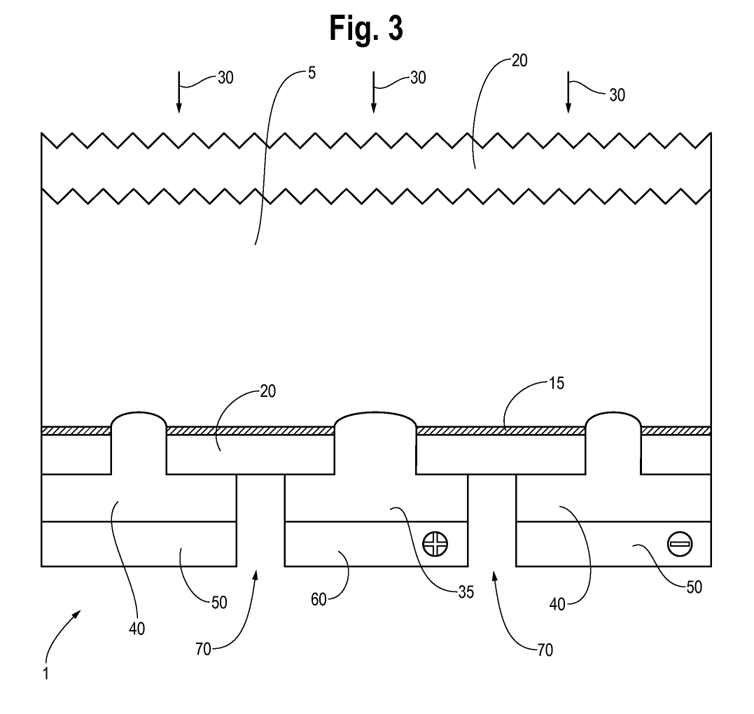

Certain embodiments of the photovoltaic cells of this invention will now be described with respect to FIGS. 2 and 3. However, it is to be understood that these are not the only embodiments of this invention.

FIG. 2 shows a cross section view of a section of an induced inversion layer, back-contact photovoltaic cell 1 in accordance with an embodiment of this invention. FIG. 2 shows a p-type silicon wafer 5 of the type suitable for manufacturing solar cells. Such wafers are known to those of skill in the art. However, it is to be understood that such wafer can also be n-type.

FIG. 2 shows an intrinsic passivation layer 10 made from amorphous silicon (a-Si:H) deposited on wafer 5. This layer can be deposited on the wafer 5 by any suitable means such as, for example, plasma enhanced chemical vapor deposition (PECVD). It can be about 4 to about 30 nm thick and, as shown in FIG. 2, can be applied on all surfaces of the wafer 5.

After depositing the intrinsic passivation layer, a doped layer 15 is applied having a doping opposite to that of the wafer. Since the silicon wafer 5 in FIG. 2 is p-type, the doped layer 15 as shown in FIG. 2 is n-type. In this example, the doped layer 15 can be doped a-Si:H, for example, a-Si:H doped with phosphorus. The doped layer 15 can be about 10 to about 30 nm in thickness and the concentration of dopant, such as, for example, phosphorus, can be about 0.1 to about 1.0 at. %. The doped layer 15 can also be an alloy of a-Si:H with carbon, nitrogen and/or oxygen. The doped layer 15 can be deposited by any convenient method such as, for example, by PECVD. As shown in FIG. 2, such doped layer can be deposited on all surfaces of the wafer.

After depositing the doped layer 15, a layer of dielectric material 20 is deposited. Such layer can be, for example, a layer of SiNₓ:H, for example, a layer about 70 to about 90 nm thick and where the value x can be about 0.4 to about 0.57 at. %. Such layer can be deposited by PECVD.

FIG. 2 shows an inversion layer 25 depicted as a dashed line around the inside perimeter of the silicon wafer. As discussed above, the inversion layer contains a high concentration of induced charge; for example, in the case of a p-type wafer, the induced charge in the inversion layer consists of electrons. This excess of electrons near the surface can be described by a local bending of the conduction and valence bands so that the Fermi level is brought close to the conduction band, thus creating an induced junction.

In the case of an n-type wafer, an inversion layer can be generated by depositing a thin passivating layer of, for example, a-Si:H and then a layer of a-Si:H doped with a p-type dopant such as, for example, boron. This doped layer can be about 10 to about 30 nm in thickness and the concentration of dopants, such as, for example, boron, can be about 0.1 to about 1.0 at. %. The doped layer can also be an alloy of Si:H with carbon, nitrogen and/or oxygen. This doped layer can be deposited by any convenient method such as, for example, by PECVD.

In the next steps, localized emitter contacts 35 and localized base contacts 40 are formed on the back side of the wafer, that is, the side of the wafer opposite to the side that will be the front, light receiving side of the completed photovoltaic cell. Arrows 30 depict light impinging on the light receiving side of induced-inversion-layer, back-contact photovoltaic cell 1.

The localized contacts can be formed, for example, by first depositing a metal by, for example, one or more deposition or plating methods, or by depositing a conductive material containing a dopant, for example aluminum, for forming local p⁺ contacts. The conductive material may be a paste or, more preferably, an ink. The metal or conductive material is preferably applied as separated dots, separated short lines, or in other suitable shapes such as continuous lines. The deposited metal or conductive material is subsequently treated so that the metal or conductive material containing the dopant reaches through the dielectric layer, the doped layer, the passivation layer and into the silicon wafer in localized regions. This can be accomplished by, for example, firing the metal or conductive material containing the dopant with a laser or other suitable source of heat such as an ion beam or electron beam. If a laser is used, it can be a Q-switched, Nd-YAG laser having a pulse duration of, for example, about 10 to about 200 nanoseconds. In this process, the metal or conductive material containing the dopant is locally heated by, for example, the laser beam and the heated, preferably molten, metal or conductive material with dopant penetrates through the layers below and forms the base 40 and emitter 35 contacts with the silicon wafer. For a p-type wafer the metal or conductive material used to form the base contacts can be as described above and is suitably aluminum or an aluminum-containing material. If the wafer is p-type the emitter contacts can be made using a metal such as antimony or bismuth, or a metal such as tin containing a dopant such as phosphorus, antimony or bismuth. In FIG. 2, the base contacts 40 can be made of aluminum and the emitter contacts 35 can be made of antimony.

In the case of localized emitter contacts 35, a contact can also be made by firing a metal through the dielectric layer into the doped layer, but in this case the intrinsic a-Si:H layer is preferably thin, for example, about 4 to 10 nm thick, so that minority carriers can move from the silicon wafer into the doped layer.

Contacts made in such manner are referred to as point contacts. However, they need not be in the shape of a point or dot. They can be any shape such as an oval or have a linear shape, such as a line shape.

In one preferred method, the localized base and emitter contacts are made by depositing a metal-containing material in the form of an ink in a desired pattern on the surface of the wafer. The pattern can be separated lines, dots, or some other suitable shape or pattern. The ink can be dried by, for example, heating prior to being fired to form the contacts.

In one such method the ink is deposited in the form of a pattern of separated dots on the back surface of the wafer. One set of separated dots comprises a material for forming the emitter contacts and the other set of dots comprises a material for forming the base contacts. The dots are then treated with a laser beam to fire the metal through the layers beneath the dots and into the silicon wafer to form the contacts.

It is preferable to electrically insulate or isolate the outer portions of the base contact 40 from the inversion layer 25. Such insulation can be achieved by including an isolation ring 45 around the outer portion of the base contacts 40. Such isolation ring 45 is shown in FIG. 2. Such isolation ring can be formed by opening holes in the passivation, doped and dielectric layers with, for example, a laser, by mechanical means, or by masking and etching the layers, and then filing the holes with a suitable dielectric material such as silicon dioxide. The metal or conductive material containing a dopant used to form the base contact 40 can be deposited over the hole having the dielectric material contained therein, and the metal or conductive material containing a dopant is then, for example, fired through the dielectric by using a laser or other suitable method, and the dielectric material will form a ring or collar 45 around the contact thereby isolating it from the inversion layer 25. Alternatively, the isolation ring can be formed by first depositing dielectric material for forming the isolation ring, and then depositing the material used to form the base contact. Then, in one firing step using, for example, a laser, the base contact material is fired through the dielectric material and through the passivation layer, the doped layer and the dielectric layer to form the base contact with the silicon wafer, and having a ring or collar of insulating dielectric material 45 surrounding the contact as shown, for example, in FIG. 2.

In the preferred method of making the photovoltaic cells of this invention, the metal containing materials used to form the contacts are deposited on the wafer in the form of an ink, and where the deposition is accomplished using a printer, and preferably an ink jet printer or an aerosol jet printer, and more preferably an ink jet printer that is controlled by a computer so that the specific pattern of printing the inks can be programmed and controlled by the computer.

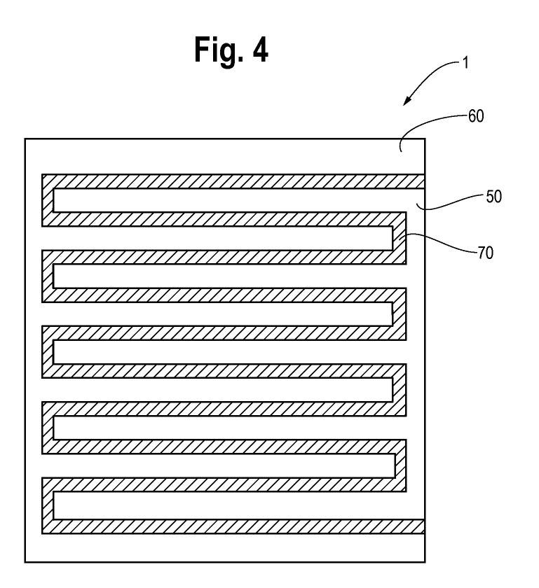

The collection of localized base contacts are electrically connected to each other and the collection of localized emitter contacts are electrically connected to each other so that the electrical current generated by exposing the photovoltaic cell to light can be collected. This can be done by, for example, applying a layer of an electrically conducting metal, such as silver, in a first pattern over and in electrical contact with the base contacts, and a second pattern over and in electrical contact with the emitter contacts, where the first pattern and the second pattern are not electrically connected. Such a pattern can be applied by one or more deposition methods such as the deposition of the metal as a vapor, or electrochemically using appropriate masks, or screen-printed using appropriate masks. Preferably, the patterns are deposited as an ink, preferably using an inkjet or aerosol jet printer as described above. FIG. 2 shows a cross-section of such pattern 60 over emitter contacts 35 and a cross-section of such pattern 50 over base contacts 40. One preferable pattern is an interdigitated finger pattern as shown in FIG. 4, where back surface of photovoltaic cell 1 has one set of fingers 50 that contact the base contacts 40, and the another set of interdigitated fingers 60 that contact the emitter contacts 35, and a space 70 that electrically separates fingers 50 and 60. In another embodiment, dopant-containing inks for forming the base and the emitter contact are deposited in a desired pattern such as a pre-selected pattern of separated dots. As described above, in the regions where the base contacts will be formed, a dielectric material can be deposited first to provide for the formation of an isolation ring. Thereafter, a layer of electrically conducting material, such as an ink containing silver, can be applied by, for example, ink jet printing a suitable pattern, such as an interdigitated pattern of fingers, over the areas where the pattern for the emitter and base contacts were printed, one set of fingers covering and connecting the dots for the base contacts, and one set of fingers covering and connecting the dots for the emitter contacts. The contacts are then formed by laser firing, as described above, the area of the fingers where the dots are printed to form the base and emitter contacts with the wafer.

As a final step, the wafer can be annealed by, for example, heating the wafer to a temperature of about 350° C. for 15 to 60 minutes or by rapid thermal processing, for example, about 700° C. for 1 minute.

FIG. 3 shows a cross section of a neutral-surface back-contact photovoltaic cell 1 in accordance with an embodiment of this invention. FIG. 3 shows a p-type silicon wafer 5. Such wafer can also be n-type. As in FIG. 2, arrows 30 in FIG. 3 depict light impinging on the front, light receiving side of the neutral-surface, back-contact photovoltaic cell 1.

FIG. 3 shows also intrinsic passivation layer 15 made from a-Si:H. This passivation layer can be deposited as described above with respect to FIG. 2 for the induced-inversion-layer back-contact photovoltaic cell. It can be about 4 to about 100 nm thick and, as shown in FIG. 3, can be applied only on the back surface of the wafer but can be on the front surface of the wafer as well.

As shown in FIG. 3, a layer of dielectric material 20 is deposited on the wafer. Such layer can be, for example, a layer of SiNₓ:H, for example, a layer about 70 to about 90 nm thick. The value x can be in the range of about 0.4 to about 0.57. Such layer can be applied as described above with respect to FIG. 2 for the induced-inversion-layer back-contact photovoltaic cell. Such layer can function as an anti-reflective coating on the front surface of the layer and as a dielectric layer on the back surface of the layer. The layer 20 on the front surface and the layer 20 on the back surface of the wafer 5 as shown in FIG. 3 can be deposited separately or at the same time. If the dielectric layers are deposited separately, then it is preferable to deposit SiNₓ:H., where the value x can be about 0.4 to about 0.57, on the front surface to act as an antireflection layer and to deposit a-SiO_{z}:H on the back surface, where the value z can be about 0.5 to about 0.66, to optimize the reflection of weakly absorbed infrared light back into the cell.

In the next steps, the emitter contacts 35 and base contacts 40 are formed on the back side of the wafer. These contacts can be formed as described for the induced inversion layer, back-contact photovoltaic cell.

The collection of localized emitter contacts are electrically connected to each other and the collection of localized base contacts are electrically connected to each other so that the electrical current generated by exposing the photovoltaic cell to light can be collected. This can be done by, for example, the methods described above for applying the interdigitated pattern of conducting material using patterns 50 and 60 as shown in FIGS. 3 and 4.

As a final step, the wafer can be annealed by, for example, heating the wafer to a temperature of about 350° C. for 15 to 60 minutes or by rapid thermal processing, for example, at about 700 C. for about 1 minute.

Only certain embodiments of the invention have been set forth and alternative embodiments and various modifications will be apparent from the above description to those of skill in the art. These and other alternatives are considered equivalents and within the spirit and scope of the invention.

U.S. Provisional Patent Application 60/895,217, filed on Mar. 16, 2007, is incorporated by reference herein in its entirety.

That which is claimed is:

1. A photovoltaic cell comprising a semiconductor wafer comprising a front, light receiving surface and an opposite back surface, a passivation layer on at least the back surface, a doped layer opposite in conductivity type to the wafer over the passivation layer, an induced inversion layer, a dielectric layer over the doped layer, and one or more localized emitter contacts and one or more localized base contacts on at least the back surface extending at least through the dielectric layer.

2. The photovoltaic cell of claim 1 wherein the one or more localized emitter contacts and the one or more localized base contacts are all on the back side of the photovoltaic cell.

3. The photovoltaic cell of claim 1 wherein the one or more localized emitter contacts and the one or more localized base contact are laser fired contacts.

4. The photovoltaic cell of claim 1 wherein at least a portion of the base contacts comprise an insulation layer electrically isolating the base contact from the inversion layer.

5. The photovoltaic cell of claim 1 wherein the semiconductor wafer comprises p-type silicon.

6. The photovoltaic cell of claim 1 wherein the semiconductor wafer comprises n-type silicon.

7. The photovoltaic cell of claim 1 wherein at least a portion of the localized base contacts extend through the dielectric layer, the doped layer and the passivation layer.

8. A photovoltaic cell comprising a semiconductor wafer comprising a front, light receiving surface and an opposite back surface, a passivation layer on at least the back surface, a doped layer opposite in conductivity type to the wafer over the passivation layer, a dielectric layer over the doped layer, and one or more localized emitter contacts and one or more localized base contacts on at least the back surface extending at least through the dielectric layer.

9. A neutral surface photovoltaic cell comprising a semiconductor wafer comprising a front, light receiving surface and an opposite back surface, a neutral passivation layer on at least the back surface, a dielectric layer over the passivation layer, and one or more localized emitter contacts and one or more localized base contacts on at least the back surface extending at least through the dielectric layer.

10. The photovoltaic cell of claim 9 wherein the localized emitter contact and localized base contacts are all on the back surface of the photovoltaic cell.

11. The photovoltaic cell of claim 9 wherein the wherein the one or more localized emitter contacts and one or more localized base contacts are laser fired contacts.

12. The photovoltaic cell of claim 9 wherein the neutral passivation layer is a-Si:H and is up to about 100 nm thick.

13. The photovoltaic cell of claim 12 wherein the a-Si:H is at least about 40 nm thick.

14. A method for manufacturing a photovoltaic cell comprising a semiconductor wafer comprising silicon, a front surface and a back surface, the method comprising:
a) depositing a passivation layer on the front and back surfaces of the wafer:
b) depositing a doped layer opposite in conductivity type to the wafer on at least the back surface of the wafer and over the passivation layer;
c) depositing a dielectric layer over at least the doped layer; and
d) forming localized base and emitter contacts on at least the back surface of the wafer and extending at least through the dielectric layer.

15. The method of claim 14 wherein the base contacts further comprise a layer of insulating material around at least a portion of the base contact.

16. The method of claim 14 wherein the photovoltaic cell comprises an induced inversion layer and the insulating material electrically insulates the base contact from the inversion layer.

17. The method of claim 14 wherein the localized base contacts and the localized emitter contacts are formed on the back surface of the photovoltaic cell in an interdigitated finger pattern.

18. The method of claim 14 wherein a first pattern of electrically conducting material is deposited on the back surface of the electrically connecting the base contacts, and a second pattern of electrically conducting material is deposited on the back surface electrically connecting the emitter contacts.

19. The method of claim 14 wherein the base and emitter contacts are laser fired contacts.

20. A method for manufacturing a photovoltaic cell comprising a semiconductor wafer comprising silicon, a front surface and a back surface, the method comprising:
a) depositing a passivation layer on at least the back surface of the wafer;
b) depositing a dielectric layer on at least the back surface of the wafer and over the passivation layer; and
c) forming localized base and emitter contacts on at least the back surface of the wafer extending at least through the dielectric layer.

21. The method of claim 20 wherein the dielectric layer is on the front and the back surface of the wafer.

22. The method of claim 20 wherein the passivation layer comprises a-Si:H and is about 4 to about 100 nm thick.

23. The method of claim 20 wherein the passivation layer and the dielectric layer is combined as one layer that is at least about 40 nm thick.

24. The method of claim 20 wherein the passivation layer and dielectric layer comprise a-Si:H.

25. The method of claim 20 wherein a thin doped layer is deposited over the passivation layer and is between the passivation layer and the dielectric layer.

26. The method of claim 25 wherein the thin doped layer comprises doped a-Si:H and is about 4 to about 20 nm thick.
